(19) United States
(12) Patent Application Publication
(10) Pub. No.: US 2012/0132802 A1
(43) Pub. Date: May 31, 2012

(54) GAS FIELD IONIZATION ION SOURCE APPARATUS AND SCANNING CHARGED PARTICLE MICROSCOPE EQUIPPED WITH SAME

(76) Inventors: Noriaki Arai, Hitachinaka (JP); Tohru Ishitani, Sayama (JP)

(21) Appl. No.: 13/381,638

(22) PCT Filed: Jun. 8, 2010
(86) PCT No.: PCT/JP2010/059718

§ 371 Date: Feb. 5, 2012

(30) Foreign Application Priority Data
Jun. 30, 2009 (JP) 2009-155525

(51) Int. Cl. H01J 27/02; H01J 37/26

(52) U.S. Cl. 250/310; 250/423 F

(57) ABSTRACT

A gas field ionization ion source apparatus is provided which is small-sized, has high-performance, and is capable of performing a tilt adjustment in a state in which an emitter tip position is maintained approximately constant. An emitter (1) is surrounded by a chamber wall (4) of an emitter chamber and ions are emitted from the tip of the emitter (1). A gas that is an ion material is introduced into the emitter chamber, through an extraction electrode (3) to which a high voltage is applied and a tube (15). The emitter (1) is cooled by a freezing means (10) through a metallic net (11) and an emitter base (12). The emitter base (12) is fixed to a movable portion (13a) of a tilting means (13). The movable portion (13a) is connected to a non-movable portion (13b) through a sliding surface (14). The sliding surface (14) forms a part of a cylindrical surface whose central axis is an axis that passes through the tip of the emitter (1) and is orthogonal to an optical axis. If the surface forms such a shape, and the amount of sliding of the sliding surface (14) is controlled, control on the tilt of the emitter (1) can be performed without moving the tip of the emitter (1).

### TECHNICAL FIELD

The present invention relates to a gas field ionization ion source apparatus for ion generation, which is mounted in a charged particle microscope for observing the surfaces of specimens such as a semiconductor device, a new material and the like.

### BACKGROUND ART

A Focused Ion Beam (abbreviated as FIB) apparatus has a Gas Field Ionization Ion Source (abbreviated as GFIS) and uses gas ions such as Hydrogen (H2), Helium (He), Argon (Ar) and the like. Such FIBs are disclosed (refer to Patent Documents 1 and 2).

These gas FIBs do not cause Ga contamination to a specimen as in the case of a Gallium (Ga: metal) FIB from a Liquid Metal Ion Source (abbreviated as LMIS) being in common use nowadays. The GFIS is capable of forming a finer beam than the Ga-FIB in terms of the fact that the energy width of a gas ion extracted from the GFIS is narrow and the size of an ion generation source of GFIS is small.

It is particularly known in the GFIS that ion source characteristics are improved, for instance, emission angle current density of an ion source is increased, due to the adoption of an emitter (hereinafter called “nano tip”) of which the tip is provided with a small protrusion (or the number of atoms of the tip of the emitter is decreased to no more than several).

The angle of an ion emission from one atom at the tip of the nano tip is as narrow as about 1°. Known microscopes equipped with the GFIS include tilting means connected to an emitter for aligning the direction of emission of an ion from the nano tip with an optical axis.

Patent Document 1 discloses that the nano tip is a three-atom termination emitter of Tungsten (W) single crystal <111>. It has been described in the Patent Document 2 that a pyramid composed of dissimilar metals such as Iridium (Ir) and Platinum (Pt) is formed at the termination of W single crystal <111>.

Patent Document 3 discloses a technology to detect the temperature of an emitter in the LMIS in non-contact form using light emitted therefrom, in order to perform temperature control of flushing heating used to eliminate impurities on the surface of the emitter.

For tilt adjustment of an emitter, a gimbal mechanism provided on the atmosphere side of an ion source chamber in the GFIS is described in the Patent Document 1.

Patent Document 4 discloses an electron gun including a technology to dispose an actuator (using a piezoelectric element) that performs centering adjustment for a cathode to Wehnelt. The technology allows the electron gun to have performance such as sufficient high emittance, etc. without having to enhance so much accuracy required for part production and assembly in the electron gun.

### PRIOR ART LITERATURE

### Patent Document

Patent Document 1: U.S. Patent No. 2008/0217555
Patent Document 2: JP-2008-140557-A
Patent Document 3: JP-5-82061-A
Patent Document 4: JP-10-321174-A

### SUMMARY OF THE INVENTION

### Problem to be Solved by the Invention

Meanwhile, in order to increase an ion emission angle current density of a GFIS, an emitter chamber that encloses the tip of an emitter therewith is provided inside an ion source chamber, and the pressure of an ion material gas introduced therein is raised to about 10-4 to 10 Pa. A hole for extracting ions is opened in a surface of a wall of the emitter chamber, which lies in the direction of emission of ions from the emitter. This wall surface also serves as an ion extraction electrode.

In order to raise a gas density in the periphery of the emitter tip, the emitter is cooled to a few tens of degrees K or less together with the introduced gas. Further, the potential of the emitter is equivalent to an ion acceleration potential for a specimen (normally, ground potential) in a scanning charged particle microscope equipped with the GFIS. It is necessary to highly insulate the emitter from an ion source enclosure (ground potential) in a range of a few kV to a few tens of kV.

Prior to the introduction of the ion material gas, it is necessary to bring the emitter chamber and the ion source chamber into ultra-high vacuum. Since vibrations and drifts of the emitter become obstacles to an observed image in a microscope observation, the maximum reduction of them is required. In order to reduce the vibrations and drifts, the emitter needs to be firmly fixed.

On the other hand, it is also necessary to provide a tilting means connected with the emitter, for aligning the direction of emission of the ions from the emitter with an optical axis.

In terms of adjusting ion extraction, the tilting means needs a structure that has the position of the emitter tip as a tilt center position, and capable of tilting with the tilt center position maintained approximately constant.

However, in the actuator for tilt adjustment described in the Patent Document 4, it is difficult to adjust a tilt in a state in which the tilt center position (emitter tip position) is maintained constant, and it is difficult to align the ion emission direction with the optical axis with a high degree of accuracy.

The GFIS tends to get large-sized to meet demands for contradictory functions such as, highly insulating and cooling to a very low temperature of the emitter, holding the ultra-high vacuum state in the ion source chamber, and fixing the emitter firmly to reduce the vibrations and drifts and controlling the tilt of the emitter. As the GFIS becomes more large-sized, large power is required for a vacuum exhaust pump and a freezing apparatus.

The GFIS in which the tilting means is disposed outside the ion source chamber has been disclosed in the Patent Document 1. In the GFIS described in the Patent Document 1, a sliding surface for implementing the tilt is disposed distant from the position of the emitter tip which is to be the tilt center. The sliding surface is disposed in the atmosphere side and the force of atmospheric pressure is applied. For this reason, the GFIS will become large-sized.

An object of the present invention is to provide a gas field ionization ion source apparatus which is small-sized, has high-performance, and is capable of performing a tilt adjustment in a state in which an emitter tip position is maintained constant, and to provide a scanning charged particle microscope equipped with the gas field ionization ion source apparatus.

### Means for Solving the Problem

In order to achieve the above object, the present invention is configured as follows:

A gas field ionization ion source apparatus of the present invention includes;

a needle-like anode emitter,

an extraction electrode forming a field to ionize and extract gas molecules at a tip portion of the emitter,

an ion source chamber having the emitter and the extraction electrode disposed therein, and

tilting means for adjusting a tilt angle of the emitter.

The tilting means is disposed inside the ion source chamber, and adjusts the tilt angle of the emitter in a state in which the position of the tip portion of the emitter is held approximately constant.

A scanning charged particle microscope of the present invention comprises;

the gas field ionization ion source apparatus,

a lens system for accelerating ions emitted from the gas field ionization ion source apparatus, focusing the ions, and irradiating the ions onto a specimen, and

a charged particle detector which detects a charged particle emitted from the specimen.

### Effects of the Invention

The present invention provides a gas field ionization ion source apparatus which is small-sized, has high-performance, and is capable of performing a tilt adjustment in a state in which an emitter tip position is maintained constant. The present invention also provides a scanning charged particle microscope equipped with the gas field ionization ion source apparatus.

### BRIEF DESCRIPTION OF THE DRAWINGS

FIG. 1 is a schematic configuration diagram showing a gas field ionization ion source (GFIS) of an embodiment 1 of the present invention;

FIG. 2 is a schematic configuration diagram showing a tilting means installed in the GFIS of the embodiment 2 of the present invention;

FIG. 3 is a schematic configuration diagram showing a scanning charged particle microscope of an embodiment 2 of the present invention;

FIG. 4 is a drive mechanism diagram of a tilting means installed in a GFIS in an embodiment of the present invention; and

FIG. 5 is a schematic configuration diagram of a gas field ionization ion source (GFIS) in an embodiment of the present invention.

### MODE FOR CARRYING OUT THE INVENTION

Embodiments of the present invention will hereinafter be described with reference to the accompanying figures.

### Embodiment 1

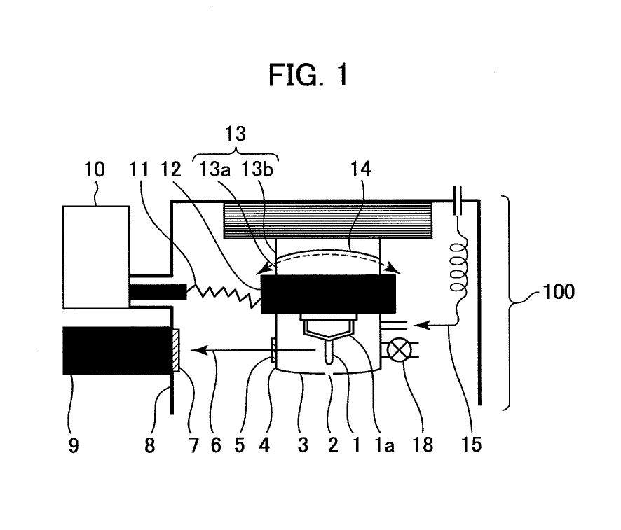

FIG. 1 is a schematic configuration diagram of a GFIS. 100 in accordance with the embodiment 1 of the present invention. In FIG. 1, an emitter 1 is which a pyramid composed of dissimilar metals such as Ir and Pt or the like is formed at a termination of a needle-like W single crystal <111>. The emitter 1 is welded and fixed to a V-shaped filament la.

The emitter 1 is an anode and is surrounded by a chamber wall 4 of an emitter chamber. A chamber wall portion facing the direction of ion emission from the tip of the emitter 1 also serves as an ion extraction electrode 3. An ion extraction hole 2 is formed in the ion extraction electrode 3. The ion extraction electrode 3 forms an electric field which is used to ionize and extract gas molecules at the tip of the emitter 1.

A gas that is an ion material is introduced into the emitter chamber through a tube 15. The tube 15 is electrically insulated from the extraction electrode 3 and the emitter 1 to which a high voltage may possibly be applied. The emitter 1 is cooled by a freezing means 10 through an emitter base (insulation material) 12 connected to a metallic net 11 with high thermal conductivity.

When He ions are emitted, for example, an ion emission angle current density increases by cooling down a He gas and an emitter temperature to about 20° K, and high ion source brightness is obtained. The emitter base (insulation material) 12 is fixed to a movable portion (movable portion that tilts together with the emitter 1) 13a of the tilting means 13. The movable portion 13a is connected with a non-movable portion 13b through a sliding surface 14. The sliding surface 14 is such that forms a part of a cylindrical surface whose central axis is an axis that passes through the tip of the emitter 1 and is orthogonal to an optical axis (in FIG. 1, an axis orthogonal to the sheet), or forms a part of a spherical surface whose central point is the tip of the emitter 1. Taking such a surface form allows the tilt of the emitter 1 to be controlled without moving the tip of the emitter 1 by controlling the amount of slide of the sliding surface 14.

When the sliding surface 14 forms a part of the cylindrical surface, the azimuth angle of a tilted surface can be controlled by controlling the rotational angle of the cylindrical surface whose central axis is the beam optical axis. When the sliding surface 14 forms a part of the spherical surface, the tilt of the emitter 1 may be controlled at a desired azimuth angle. A tilt angle necessary for optical-axis alignment of the emitter 1 in a GFIS 100 mounted in a scanning charged particle microscope is plus or minus 4° at the maximum and a tilt angle control resolution is 0.01° at the maximum. This is based on the accuracy of fixing of the axis of the emitter 1 to the emitter base 12, the accuracy of coincidence between the axis of the emitter 1 and a desired crystal orientation, etc.

The sliding surface 14 of the tilting means 13 is a part of a cylindrical surface whose central axis is an axis passing through the tip of the emitter 1 or a spherical surface whose central point is the tip of the emitter 1, and is not a flat surface. For this reason, the larger the radius of the sliding surface, that is, the radius from the tip of the emitter 1 to the cylindrical surface or the spherical surface, the more the area of the sliding surface that covers a specific tilt angle increases. If this radius is small, the sliding surface can also be reduced (that is, a size reduction is enabled), so that precision machining becomes easy. However, if it is too small, the normal precision machining becomes difficult.

In the embodiment 1 of the present invention, the movable portion 13a and non-movable portion 13b of the tilting means 13, and the sliding surface 14 between the two portions exist within an ion source chamber. The radius of curvature of the sliding surface 14 is smaller than the radius of a vacuum enclosure for the ion source. Atmospheric pressure is not applied to the sliding surface 14, and the movable portion 13a and the non-movable portion 13b can be brought into less size and weight.

A lower limit value of a force for allowing the sliding surface 14 to make sliding corresponds to the total force of the gravity and the frictional force of each related part. The power of a force generation part for tilting and a mechanical part for transferring a generated force can also be reduced in size and lightened in weight.

In the embodiment 1 of the present invention, a piezoelectric element is adopted for the operation of the tilting means 13. Thus, the size [mm] thereof could be reduced to about 15×15×10 and the weight thereof could be lightened to about 25 g. The miniaturization of the tilting means 13 is very important in reducing cooling power. A high-precision and stable tilt control of the emitter 1 is enabled in a temperature between about 20° K and the room temperature.

Since the small-sized tilting means 13 is located within the ion source (chamber surrounded by the vacuum enclosure 8 for the ion source), the ion source itself could be brought into less size and weight. As a result, it brings about a great effect on the enhancement of anti-vibrations of the scanning charged particle microscope and miniaturization of the microscope itself.

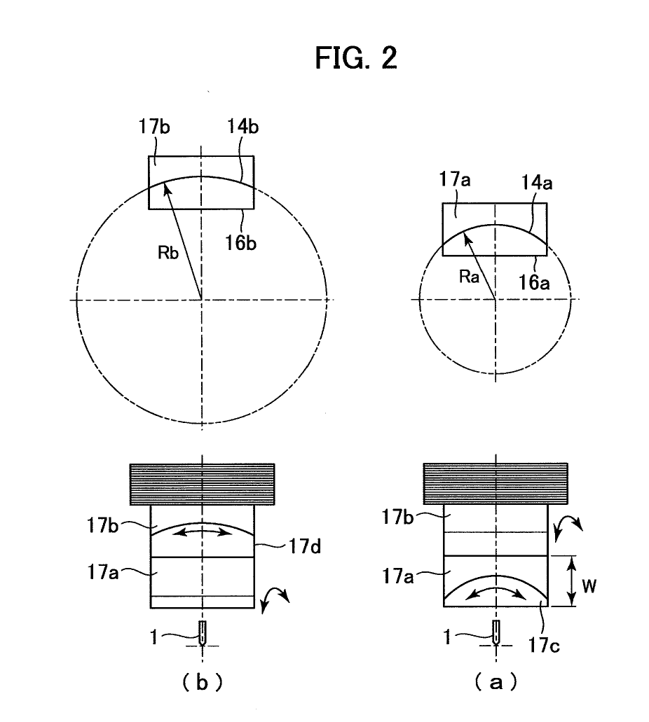

A structure most useful for the tilting means 13 in terms of ease of production and ease of control is a structure in which as shown in FIGS. 2(a) and 2(b), two tilting means, a tilting means 17a and a tilting means 17b are combined together. The tilting means 17a and the tilting means 17b are such that their sliding surfaces 14a (FIGS. 2(a)) and 14b (FIG. 2(b)) are partial surfaces of cylinders having each central axis placed in the tip of an emitter 1, and having radii which are different from each other respectively.

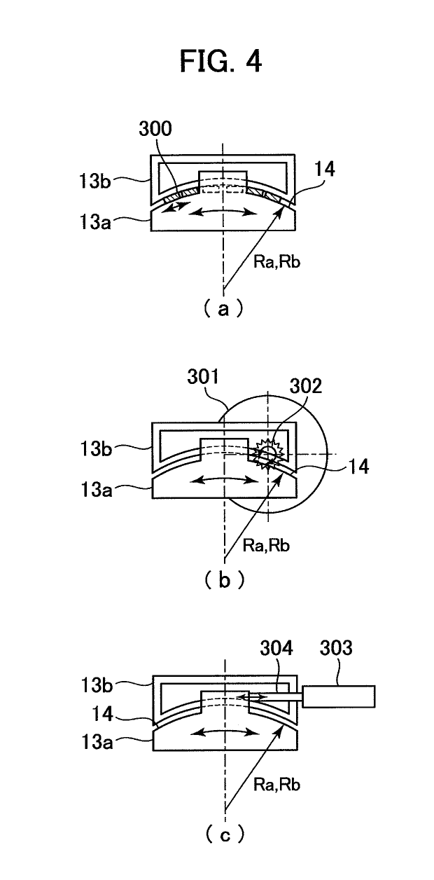

A first movable portion 17d is driven by the tilting means 17b. A second movable portion 17c that supports the emitter 1 is driven by the tilting means 17a. The tilting means 17a and 17b are a non-movable portion 13b of FIG. 4, and the first movable portion 17d and the second movable portion 17c are a movable portion 13a of FIG. 4.

The sliding surfaces 14a (second sliding surface) and 14b (first sliding surface) are relatively rotated 90° around a beam optical axis and combined vertically. The sliding surfaces 14a and 14b are controlled independently, so that the emitter 1 can be tilted in orthogonal directions. Therefore, the emitter 1 can be tilted in an arbitrary direction by combining the tilt of the sliding surfaces 14a and 14b. The first sliding surface 14b is a surface of a shape that forms a part of a cylindrical surface, whose central axis is a first straight line that passes through the tip of the emitter 1 and is approximately perpendicular to the direction of emission of ions from the emitter 1. The second sliding surface 14a is a surface of a shape that forms a part of a cylindrical surface whose central axis is a second straight line approximately perpendicular to the first straight line.

In this case, each of the sliding surfaces 14a and 14b is simple in structure and control because a piezoelectric element may be disposed one-dimensionally along guides on an arch coincident to a sliding direction.

In addition, a tilt radius Ra of the sliding surface 14a and a tilt radius Rb of the sliding surface 14b have a relation of Ra<Rb. Movable surfaces 16a and 16b of the tilting means 13 are parallel to each other when the angle of tilt is 0°. If the interval between the two movable surfaces is set as W, when Rb−Ra=W, the tilting means can be tilted in an arbitrary direction around the emitter 1.

On the other hand, when the sliding surface 14 forms a spherical surface, the number of sliding surfaces may be one. However, piezoelectric elements are required to be two-dimensionally disposed on the spherical surface, therefore the number of elements increases and the working accuracy of disposing the elements on the spherical surface becomes very high. Controlling of the piezoelectric element is also complicated and the cost-effectiveness is low.

Meanwhile, instead of an inchworm-type moving mechanism such as shown in FIG. 4(a), which is such that utilizes the expansion and contraction of one or more piezoelectric elements 300 disposed at the sliding surfaces 14a and 14b, other means for generating a tilting force may be applied. For instance, a rotating mechanism using a gear wheel 302 connected to a motor 301 as shown in FIG. 4(b), or a push-pull mechanism using a linear actuator 303 as shown in FIG. 4(c) may be applied.

The piezoelectric elements 300 shown in FIG. 4(a) are arranged along the surface of the non-movable portion 13b side that is disposed parallel to the sliding surface 14. The piezoelectric elements 300 adhere tightly to the sliding surface 14. When a pulse-like voltage is applied to the piezoelectric elements 300, the piezoelectric elements 300 can expand and contract in one direction so that the sliding surface 14 can be moved with a frictional force.

The motor 301 shown in FIG. 4(b) is disposed inside or outside the tilting means and connected to the gear wheel 302 with a coaxial gear wheel or an additional gear wheel. Gear teeth are formed on the sliding surface 14 so as to engage with the gear wheel 302.

A shaft 304 expanded and contracted by the linear actuator 303 is fastened to the movable portion 13a of the tilting means shown in FIG. 4(c) with a part that is angularly flexible to the shaft 304, such as a universal joint. The movable portion 13a of the tilting means 13 is attached in such a manner that the surface of the non-movable portion 13b parallel to the sliding surface 14 functions as a guide. Thus, the shaft 304 is expanded and contracted to thereby enable tilt movement of the movable portion 13a of the tilting means 13 along the sliding surface 14.

The mechanisms shown in FIGS. 4(b) and 4(c) however have many mechanical movable parts including the insides of the motor 31 and the linear actuator 303. They are more complex and cause much outgas from the parts, thereby make difficulties in achieving ultra-high vacuum. The reliability of a mechanical operation is inferior to that of the former (the mechanism shown in FIG. 4(a)) in terms of a heat shrinkage in cooling to an extreme low temperature lowering and an increase in frictional resistance in vacuum. It is also inferior to the former in terms of having a large amount of backlash of tilt control.

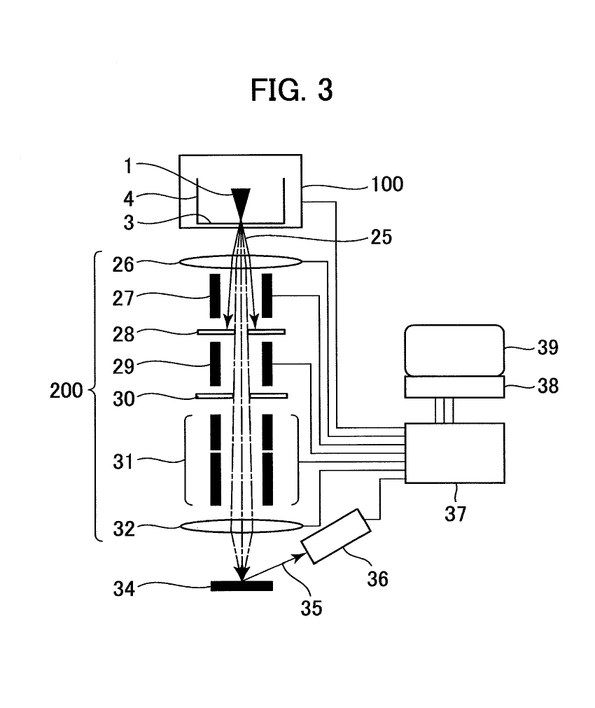

Incidentally, an operator is able to issue a command for driving the piezoelectric elements 300, the motor 301 and the linear actuator 303 using a command means such as a personal computer or the like while observing the tilt angle of the emitter 1. As will be described later, it is possible to detect the position of irradiation of an ion beam and adjust the tilt angle of the emitter 1 where the GFIS 100 of the present invention is mounted onto the scanning charged particle microscope. In this case, the tilt angle of the emitter 1 can also be automatically changed (adjusted) by a PC 38 shown in FIG. 3.

The technology described in the Patent Document 1, which is the known technology, will now be explained by way of comparison with the embodiment 1 of the present invention. In the technology described in the Patent Document 1, both movable and non-movable portions of a tilting means serves as a part of a vacuum enclosure wall for an ion source. For this reason, both portions become thick, large-sized parts to resist the atmospheric pressure without any deformation, and the weight is also increased. Further, since the sliding surface between the two portions is pressed by the atmospheric pressure, a very large force is needed to slide them for making a tilt. The power of a generation portion for generating the large force, and a mechanical part for transferring the force therefore become large-sized. Such increases in size and weight are greatly disadvantageous in terms of vibration proof and cooling efficiency of the ion emitter.

In contrast, in the embodiment 1 of the present invention, the tilting means 13 is disposed within the ion source chamber whose inside is almost vacuum and does not require the mechanical strength in regard of the atmospheric pressure, whereby can be brought into less size and weight.

Further, in the embodiment 1 of the present invention, the tilt angle of the emitter 1 can be adjusted in a state in which the position of the tip of the emitter 1 is held constant. For this reason, the adjustment control to which the ion source apparatus is attached for bringing the direction of emission of ions from the emitter 1 into alignment with the optical axis of the charged particle microscope, can be performed easily and highly accurately.

A description will next be made of the exchange of the emitter equipped with the tilting means 13 in the embodiment 1 of the present invention, and disposed within the emitter chamber.

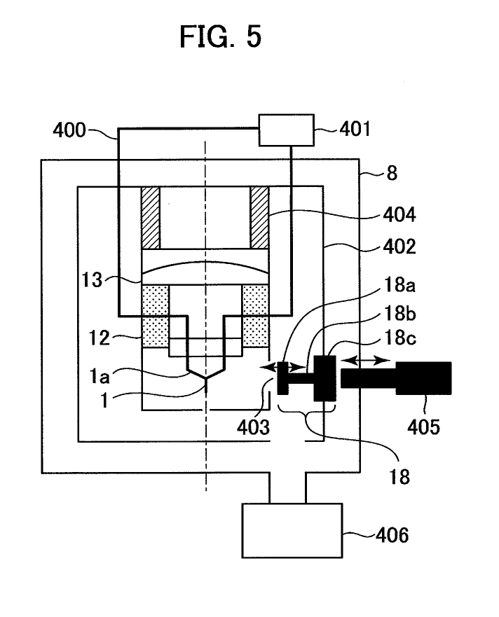

Upon the exchange of the emitter that accompanies break of the vacuum of the GFIS 100, a base with a new emitter 1 is fixed to an emitter base (insulation material) 12 and arranged as an ion source. An emitter chamber is connected to an emitter chamber with an exhaust valve 18 (shown in FIGS. 1 and 5). When the emitter is to be exchanged, the exhaust valve 18 is opened to exhaust the emitter chamber and ion source chamber, thereby bringing the same into ultra-high vacuum. Thereafter, the emitter 1 is subjected to flushing (short-time high-temperature heating) and annealing (long-time high-temperature heating) in the vacuum by resistive heating of a V-shaped filament 1a and thereby cleaned. When an ion material gas is introduced into the ionization chamber to emit ions, the exhaust valve 18 is closed. This valve opening/closing can be manipulated automatically in conjunction with a manipulation command from the scanning charged particle microscope or by non-cooperative manual.

However, when the exhaust velocity of the ionization chamber is sacrificed and the reduction of a thermal input to the ionization chamber, the thermal input caused by the thermal radiation and thermal conduction, to be cooled are preferred, the exhaust vent 403 for exhaustion and the exhaust valve 18 may not be provided.

An internal structure of the vacuum enclosure 8 will be described in further detail with reference to FIG. 5.

The inside of the vacuum enclosure 8 of the ion source is exhausted to an ultra-high vacuum level by a vacuum pump 406. The emitter 1 in the vacuum enclosure 8 is cooled to a very low temperature. In addition, a heat shield 402 that is set to a temperature lower than the temperature of the vacuum enclosure 8 and a temperature higher than that of the emitter 1, specifically, 100° K or so may be provided to prevent thermal radiation from the vacuum enclosure 8 whose temperature is the room temperature.

In this case, the tilting means 13 by which the emitter base 12 is held may be retained by the thermal shield 402 through a thermal insulation portion 404, or by the vacuum enclosure 8 of the ion source while thermal anchor is taken by the thermal shield 402. The thermal insulation portion 404 should be made with a material with low thermal conductivity, such as plastic or a thin-walled metal pipe.

The flushing and annealing are performed by taking out an electric conductive wire 400 connected to the V-shaped filament 1a outside the vacuum and connecting it to a heating power supply 401. Further, since the pressure of the vacuum enclosure 8 of the ion source is temporarily changed to an atmospheric pressure upon emitter exchange, it is necessary to exhaust atmospheric air or nitrogen that is a purge gas by the vacuum pump 406 upon emitter exchange.

The inside of the vacuum enclosure 8 is exhausted to the ultra-high vacuum level to prevent the purity of the ion material gas from deterioration. Upon this procedure, the inside and outside of the vacuum enclosure 8 need to be heated (baked) to degas (remove gas) an impurity gas adsorbed or stored in the vacuum enclosure 8 by the release to atmospheric pressure.

The pressure of the impurity gas in the ionization chamber increases upon baking. Therefore, the exhaust valve 18, which is capable of opening and closing the exhaust vent 403 disposed on the sidewall of the ionization chamber, is retreated (opened) to bring the exhaust vent 403 into an open state. The exhaust velocity by the vacuum pump 406 may thereby be improved and the ultra-high vacuum in the ionization chamber may be achieved.

The vacuum exhaust valve 18 can be opened and closed by a valve drive mechanism 405. However, if the vacuum exhaust valve 18 and the valve drive mechanism 405 are always connected to each other, the inflow of heat from the room temperature into the ionization chamber to be cooled increases, and the temperature may not be lowered.

Thus, the vacuum exhaust valve 18 is generally set in a normal closed state in which blocks the exhaust vent 403, and the vacuum exhaust valve 18 is separated from the valve drive mechanism 405 by a holding part 18c. The holding part 18c is connected to the thermal shield 402, and linked by a valve seal 18a and a thin-walled pipe 18b that is a heat insulation material. It is therefore possible to suppress the inflow of heat into the ionization chamber extremely low.

Consequently, only when baking or exhaust of the ion material gas is conducted, the valve drive mechanism 405 is connected to the holding part 18c. The motion of the valve drive mechanism 405 is transferred to the valve seal 18a, and thereby makes it possible to eliminate the unnecessary inflow of heat into the ionization chamber.

In addition, an important case to be considered is a case in which trouble occurs in the ion emitter 1 in the regeneration of a nano tip, and measurement of the temperature of the emitter 1 while flushing or annealing is required.

The emitter 1 is connected to a high voltage line, and also in terms of cooling efficiency, it is difficult to provide a temperature measuring thermocouple in the periphery of the emitter 1. In order to meet this difficulty, a temperature measurement using light emitted from the emitter 1 may be applied.

Upon the regeneration of the nano tip in the scanning charged particle microscope equipped with the GFIS, the flushing or the short-time annealing of the emitter 1 is generally performed without turning off the power of the cooling means (to avoid time prolongation of the temperature drift in the cooling system). In the control for holding the power of the flushing or the annealing constant, heating temperature is greatly affected by the temperature of the emitter base 12 (by thermal conduction) and the temperature of substances including the emitter 1 (by thermal radiation).

The resistance of the V-shaped filament (W wire) 1a to which the emitter 1 attached is also a function of temperature. Even if the resistance is controlled constant, above affects are caused. It is therefore desirable that the temperature of the emitter is measured in order to heat the emitter to a desired emitter temperature.

In the embodiment 1 of the present invention, as shown in FIG. 1, the light 6 emitted from the emitter 1 is measured by an emitted-light-using temperature measuring means 9 through an ion source chamber window 7. Although the emitter chamber sidewall 4 exists in an optical path for the emitted light 6, a part 5 that is transparent to the emitted light 6 is formed in the emitter chamber sidewall 4.

This part 5 has the effect of blocking a gas to be introduced into the emitter chamber. Passage and diffusion of the introduced gas, which may occur in cases such as an opening is provided in an emitter chamber sidewall 4, therefore does not occur. For this effect, it is possible to avoid a reduction in the efficiency of the supply of gas to the emitter tip, which occurs if the gas leaks out from the opening. The effect also avoids the expansion of an ion beam due to an increase in the probability of collision between an extracted ion and a gas atom (or a molecule), which is caused by the leaked gas deteriorating the degree of vacuum in the rear of the hole of the ion extraction electrode.

Further, in the embodiment 1 of the present invention, if the emitter chamber sidewall 4 is fabricated by a transparent material with high thermal conductivity, sapphire for instance, the light emitted from the emitter 1 can be measured without providing the transparent part 5, and a similar effect can still be obtained.

In the embodiment 1 of the present invention, the optical path from the window 7 of the ion source chamber wall to the emitted-light-using temperature measuring means 9 is linear. However, a part or the whole optical path may be replaced by an optical fiber. This allows the optical path to be curved while maintaining electrical insulation.

If the window 7 of the ion source chamber and other parts are sealed with the end face of the optical fiber, the passage/diffusion of the gas introduced from the window can also be prevented.

The technology described in the Patent Document 3 that is of the known technology will be explained as a comparative example of the embodiment 1 of the present invention. In the non-contact temperature detection using the light radiated from the emitter, which is disclosed in the Patent Document 3, a liquid metal that wets the emitter itself is an ion material, which is a LMIS.

In the GFIS, however, the ion material is a gas, and the emitter is provided within the emitter chamber to efficiently supply a gas atom (or a molecule) to the tip of the emitter. For this reason, the light emitted from the emitter in the heating does not leak out other than the light emitted to the direction of an ion extraction hole (also serves as an ion extraction hole of the extraction electrode) provided within the emitter chamber.

If an opening for the emitted-light detection is provided in the emitter chamber, the ion material gas leaks out from the opening and cannot be efficiently supplied to the tip of the emitter. Further, the leaked gas deteriorates the degree of vacuum in the rear of the hole of the ion extraction electrode, and the probability of collision between extracted ions and gas atoms (or molecules) is increased. The performance of a beam is thereby degraded.

On the other hand, in the embodiment 1 of the present invention, the emitter temperature can be detected without degrading the beam performance.

### Embodiment 2

An embodiment 2 of the present invention will next be explained. FIG. 3 is a schematic configuration diagram of a scanning charged particle microscope showing the embodiment 2 of the present invention.

In FIG. 3, the scanning charged particle microscope showing the embodiment 2 of the present invention includes a lens system 200 which accelerates ions 25 from an emitter 1 of a GFIS 100, focuses the ions 25 and irradiates the same onto a specimen, and a charged particle detector 36 which detects a charged particle 35 emitted from the specimen. The GFIS 100 has a configuration equivalent to the GFIS described in the embodiment 1.

The ions 25 are focused on the specimen 34 by a focusing lens 26 and an objective lens 32 that are principal components of the lens system 200. A beam deflector/aligner 27, a variable beam limit aperture 28, a blanking electrode 29, a blank beam stop plate 30 and a beam deflector 31 are disposed between the lenses 26 and 32.

The secondary electron 35 emitted from the specimen 34 is detected by the secondary electron detector 36. A beam control unit 37 controls the GFIS 100, the focusing lens 26, the objective lens 32, the upper-stage beam deflector/aligner 27, the lower-stage beam deflector 31, the secondary electron detector 36, etc.

A PC 38 controls the beam control unit 37 and performs processing and storage of various data. An image display means 39 displays a scanning ion microscope (Scanning Ion Microscope: abbreviated as SIM) image and a control screen at the PC 38.

When an Ar gas or a Ne gas is introduced into the GFIS 100, and an Ar ion or a Ne ion is emitted, the emitter 1 is cooled to about 70° K. When a He gas is introduced and a He ion is emitted, the emitter 1 is cooled to about 20° K to enhance the brightness of an ion source.

Particularly, when the emitter 1 is cooled to a low temperature of about 20° K as in a He ion microscope, the structure of the ion source is required to have good cooling efficiency. A small-sized structure such as the structure described in the embodiment 1 of the present invention, which the tilting means 13 is connected with the emitter 1 and disposed within the ion source chamber is very suitable.

An image observed by a scanning He ion microscope is sensitive to top surface information of a specimen, and also has characteristics such as high-resolution or a large focal depth. Since the He ion is light, damage to the specimen due to irradiation is low. On the other hand, since the Ne and Ar ions are heavy, their irradiation cause sputtering, that can be used for the application of micro-fabrication.

When the GFIS 100 mounted on the upper part of the scanning charged particle microscope is large-sized and heavy, it tends to swing from side to side and therefore tends to cause an error in a microscopic image due to vibration.

The high-resolution scanning charged particle microscope according to the embodiment 2 of the present invention can be brought into less size and weight without degrading the ion source performance of the GFIS 100. It does not swing from side to side easily and is capable of suppressing the occurrence of an error due to vibration in a microscopic image.

Further, in the emitter 1 of the GFIS 100, the tilt angle thereof can be adjusted in a state in which the position of the tip of the emitter 1 is held constant. For this reason, adjustments to the direction of ion emission and the optical axis of the scanning charged particle microscope can be performed easily and highly accurately.

### Embodiment 3

An embodiment 3 of the present invention will next be explained.

When a high voltage that is negative to an extraction electrode 3 is applied to an emitter 1 in an ultra-high vacuum, electrons are emitted from the tip of the emitter 1 by a strong electric field. Thus, a GFIS 100 can also be operated as a field emission (Field Emission: abbreviated as FE) electron source apparatus.

The embodiment 3 of the present invention is an example of which the present invention is applicable to both an electron source apparatus and a scanning electron microscope. The configuration of the embodiment 3 of the present invention is equivalent to that of the examples shown in FIGS. 1 and 3.

The embodiment 3 of the present invention will be explained with reference to FIG. 3. A lens system 200 is an electrostatic system. Therefore, if a lens potential to be applied is reversed in positive/negative polarity and adjusted, the lens system 200 can also serve as a scanning electron microscope (Scanning Electron Microscope: abbreviated as SEM).

When an electron is extracted from the emitter 1, the angle of emission thereof from one atom ranges from 2° to 3°, and is wider by about 1° than that of the ion emission. However, an emitter axis of a case which the axis of an electron emission from the emitter 1 is aligned with a SEM optical axis, and an emitter axis of a case which the axis of an ion emission is aligned with a SIM optical axis does not always correspond. It is necessary to perform an axial alignment of the emitter 1 by the tilting means 13 at each of the SEM and SIM.

However, if the angles of tilts based on their axial alignment, the potentials of lens systems, and axial adjustment conditions are once stored in the PC 38, they can be automatically switched by selecting the operation of the SEM and SIM.

According to the embodiment 3 of the present invention, a gas field ionization ion source apparatus which is small-sized, has high-performance and is capable of performing a tilt adjustment in a state in which the position of the tip of an emitter is being maintained constant, and a scanning charged particle microscope equipped therewith can be provided. The gas field ionization ion source apparatus equipped to the scanning charged particle microscope can also serve as an electron source apparatus.

### EXPLANATION OF REFERENCE NUMERALS

1 . . . emitter, 2 . . . hole for ion extraction, 3 . . . extraction electrode, 4 . . . emitter chamber wall, 5 . . . transparent part, 6 . . . light emitted from emitter, 7 . . . window of ion source chamber wall, 8 . . . vacuum enclosure of ion source, 9 . . . emitted-light-using temperature measuring means, 10 . . . freezing means, 11 . . . metallic net, 12 . . . emitter base (insulation material), 13 . . . tilting means, 13a . . . movable portion of tilting means, 13b . . . non-movable portion of tilting means, 14, 14a, 14b . . . sliding surfaces, 15 . . . metallic tube, 16a, 16b . . . movable surfaces of tilting means, 17a, 17b . . . tilting means, 17c . . . second movable portion, 17d . . . first movable portion, 18 . . . exhaust valve, 18a . . . valve seal, 18b . . . thin-walled pipe, 18c . . . holding part, 25 . . . emitted ion beam, 26 . . . focusing lens, 27 . . . beam deflector/aligner, 28 . . . variable beam limit aperture, 29 . . . blanker, 30 . . . blank beam stop plate, 31 . . . beam deflector, 32 . . . objective lens, 34 . . . specimen, 35 . . . secondary electron, 36 . . . secondary electron detector, 37 . . . beam control unit, 38 . . . PC, 39 . . . image display means, 100 . . . gas field potential ion source (GFIS), 200 . . . lens system, 300 . . . piezoelectric element, 301 . . . motor, 302 . . . gear wheel, 303 . . . linear actuator, 304 . . . shaft, 400 . . . electric conductive wire, 401 . . . heating power supply, 402 . . . heat shield, 403 . . . exhaust vent, 404 . . . thermal insulation portion, 405 . . . valve drive mechanism, 406 . . . vacuum pump.

1-10. (canceled)

11. A gas field ionization ion source apparatus comprising:
a needle-like anode emitter;
an extraction electrode for forming an electric field, and thereby ionizing and extracting gas molecules at a tip portion of the emitter;
an ion source chamber having the emitter and the extraction electrode disposed therein; and
tilting means for adjusting a tilt angle of the emitter,
the gas field ionization ion source apparatus including:
an emitter chamber which is stored in the ion source chamber and a gas for supplying the gas molecules is introduced to, and
a thermal shield disposed in the periphery of the emitter chamber and inside the ion source chamber,
wherein the tilting means is disposed inside the ion source chamber, and the tilt angle of the emitter is adjusted by the tilting means in a state in which the position of the tip portion of the emitter is held approximately constant.

12. The gas field ionization ion source apparatus according to claim 11, wherein the tilting means has a movable portion which is connected with the emitter and tilts with the emitter, and a non-movable portion which moves the movable portion through a sliding surface.

13. The gas field ionization ion source apparatus according to claim 12, wherein the sliding surface of the tilting means is a surface of a shape that forms a part of a cylindrical surface whose central axis is a line that passes through the tip of the emitter.

14. The gas field ionization ion source apparatus according to claim 13, wherein the movable portion of the tilting means has a first movable portion driven by the non-movable portion through a first sliding surface, and a second movable portion driven by the first movable portion through the first movable portion and a second sliding surface,
wherein the first sliding surface is a surface of a shape that forms a part of a cylindrical surface whose central axis is a first straight line passing through the tip of the emitter and approximately orthogonal to the direction of ion emission of the emitter, and
wherein the second sliding surface is a surface of a shape that forms a part of a cylindrical surface whose central axis is a second straight line approximately orthogonal to the first straight line.

15. The gas field ionization ion source apparatus according to claim 14, wherein the non-movable portion of the tilting means has a first piezoelectric element that drives the first movable portion, and the first movable portion of the tilting means has a second piezoelectric element that drives the second movable portion.

16. The gas field ionization ion source apparatus according to claim 11, wherein at least a part of the emitter chamber is formed of a transparent member that transmits light, and
wherein the gas field ionization ion source apparatus having emitted-light-using temperature measuring means, for measuring the temperature of the emitter based on the emitted light that passed through the transparent member of the emitter.

17. The gas field ionization ion source apparatus according to claim 16, wherein a movable portion of the tilting means has a first movable portion driven by a non-movable portion through a first sliding surface, and a second movable portion driven by the first movable portion through the first movable portion and a second sliding surface,
wherein the first sliding surface is a surface of a shape that forms a part of a cylindrical surface whose central axis is a first straight line passing through the tip of the emitter and approximately orthogonal to the direction of ion emission of the emitter, and
wherein the second sliding surface is a surface of a shape that forms a part of a cylindrical surface whose central axis is a second straight line approximately orthogonal to the first straight line.

18. A scanning charged particle microscope comprising:
the gas field ionization ion source apparatus according to claim 11;
a lens system for accelerating ions emitted from the gas field ionization ion source apparatus, focusing the ions, and applying the same onto a specimen; and
a charged particle detector for detecting a charged particle emitted from the specimen.

19. The scanning charged particle microscope according to claim 18, wherein the ions emitted from the gas field ionization ion source apparatus are Helium ions.
